(19) United States
(12) Patent Application Publication
(10) Pub. No.: US 2009/0171599 A1
(43) Pub. Date: Jul. 2, 2009

(54) Battery Discharge Indicator For Golf Car

(75) Inventors: Oliver A. Bell, Aiken, SC (US); Warren Clark, Evans, GA (US)

Correspondence Address: HARNESS, DICKEY & PIERCE, P.L.C., P.O. BOX 828, BLOOMFIELD HILLS, MI, 48303, US

(73) Assignee: TEXTRON INC., Providence, RI (US)

(21) Appl. No.: 11/966,363

(22) Filed: Dec. 28, 2007

(51) Int. Cl. G01R 31/36; G06F 19/00

(52) U.S. Cl. 702/63

(57) ABSTRACT

A system is disclosed for determining battery state-of-charge (SoC) in an electric vehicle. The system includes an inverter that converts battery power to an alternating current, a current sensor that generates a signal indicative of a magnitude and direction of the alternating current, a first analog-to-digital converter (A2D) that converts the signal to current data, and a central processing unit (CPU) that periodically stores a present value of the current data to an associated memory and determines the SoC based on the stored current data.

### FIELD OF THE INVENTION

The present invention relates to determining a state of charge (SoC) of a battery.

### BACKGROUND OF THE INVENTION

Electric vehicles generally rely on rechargeable batteries to provide some or all of the energy to propel the vehicle. It is therefore important for vehicle users to have an indication of the SoC of the vehicle battery.

Known SoC indicators monitor the battery current and/or voltage over time to determine the SoC. In some vehicles, however, it may not be practical or economically feasible to directly monitor the battery current. An alternative method for determining SoC is needed for those vehicles.

### SUMMARY OF THE INVENTION

A system for determining battery state-of-charge (SoC) in an electric vehicle includes an inverter that converts battery power to an alternating current, a current sensor that generates a signal indicative of a magnitude and direction of the alternating current, a first analog-to-digital converter (A2D) that converts the signal to current data, and a central processing unit (CPU) that periodically stores a present value of the current data to an associated memory and determines the SoC based on the stored current data.

In other features the CPU stores in a memory corresponding time data with the current data. The CPU accesses a look-up table to determine the SoC. The system further includes a temperature sensor that generates battery temperature signal and a second A2D that generates battery temperature data based on the battery temperature signal. The CPU determines the SoC based on the stored current data and the temperature data. The system includes a clock that generates time data. The CPU determines the SoC after the time data indicates a predetermined period has passed. The alternating current is equal to zero during the predetermined time. The system includes a third A2D that generates battery voltage data based on a voltage of the battery power. The CPU determines the SoC based on the stored current data and the battery voltage data.

A method for determining battery state-of-charge (SoC) in an electric vehicle converts battery power to an alternating current, generates a signal indicative of a magnitude and direction of the alternating current, converts the signal to current data, periodically stores a present value of the current data, and determines the SoC based on the stored current data.

In other features the periodically storing step includes storing corresponding time data with the current data. The method includes accessing a look-up table to determine the SoC. The method includes generating a battery temperature signal and generating battery temperature data based on the battery temperature signal. The SoC is determined based on the stored current data and the temperature data. The method includes generating time data. The SoC is determined after the time data indicates a predetermined period has passed. The alternating current is equal to zero during the predetermined time. The method includes generating battery voltage data based on a voltage of the battery power. The SoC is determined based on the stored current data and the battery voltage data.

A system for determining battery state-of-charge (SoC) in an electric vehicle includes inverter means for converting battery power to an alternating current, current sensor means for generating a signal indicative of a magnitude and direction of the alternating current, first converter means for converting the signal to current data, and processing means for periodically storing a present value of the current data to memory means for storing data and for determining the SoC based on the stored current data.

In other features the processing means stores in the memory means corresponding time data with the current data. The processing means accesses look-up table means for determining the SoC. The system includes temperature sensing means for generating a battery temperature signal and second converter means for generating battery temperature data based on the battery temperature signal. The processing means determines the SoC based on the stored current data and the temperature data. The system includes clock means for generating time data. The processing means determines the SoC after the time data indicates a predetermined period has passed. The alternating current is equal to zero during the predetermined time. The system includes third converter means for generating battery voltage data based on a voltage of the battery power. The processing means determines the SoC based on the stored current data and the battery voltage data.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a functional block diagram of an electric drive system of a vehicle;

FIG. 2 is a flow chart of a method for determining the SoC of a battery in an electric drive system; and

### DETAILED DESCRIPTION OF THE PREFERRED EMBODIMENTS

The following description of various embodiments is merely exemplary in nature and is in no way intended to limit the present teachings, application, or uses. Throughout this specification, like reference numerals will refer to similar elements.

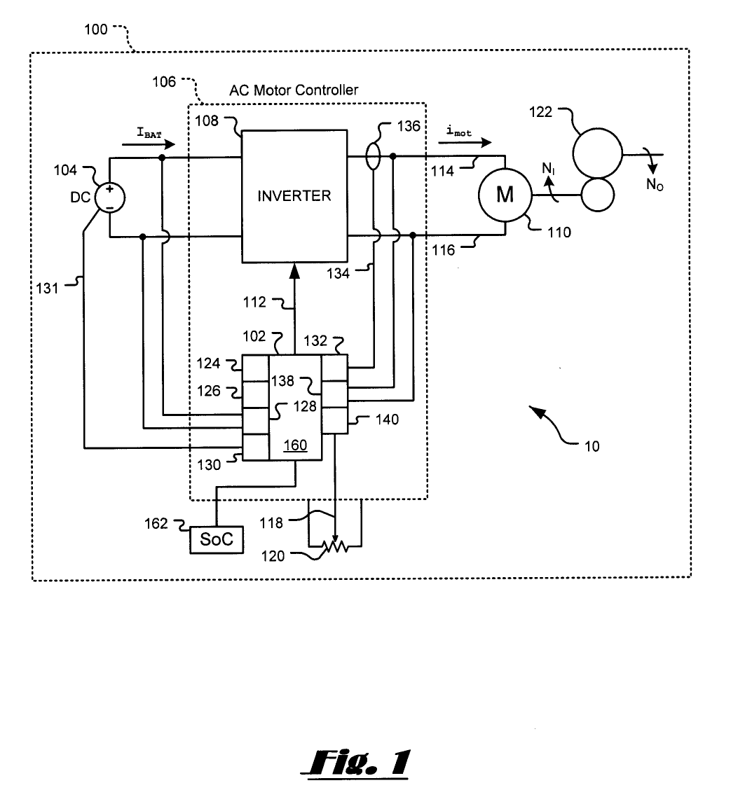

FIG. 1 shows one of various embodiments of an electric vehicle drive system 10. Drive system 10 is included in a vehicle represented by dashed box 100. Drive system 10 includes a microcontroller 102 that, in pertinent part, determines the SoC of a rechargeable battery 104.

Battery 104 provides a DC battery current I_{BAT} to an AC motor controller 106. AC motor controller 106 includes an inverter 108 that converts the battery current I_{BAT} to an alternating current Iₘₒₜ. The battery current I_{BAT} is generally unequal to alternating current Iₘₒₜ since AC motor controller 106 draws a portion of battery current I_{BAT} to run inverter 108 and microcontroller 102. A frequency of the alternating current Iₘₒₜ determines the speed of a motor 110 and is based on a motor speed signal 112. A first power lead 114 and a second power lead 116 carry the alternating current Iₘₒₜ and connect inverter 108 to motor 110. In some embodiments two additional pairs of first power lead 114 and second power lead 116 can be used to carry a 3-phase alternating current Iₘₒₜ.

Motor speed signal 112 is based on a pedal position signal 118, which can be generated by a potentiometer 120 that is associated with an accelerator pedal (not shown) of vehicle 100. An output shaft of motor 108 rotates at a first RPM N_{I} and is connected to an input shaft of a gear reduction box 122. An output shaft of gear reduction box 122 rotates at a second RPM N_{O} and provides an output torque for propelling vehicle 100. Microcontroller 102 generates the motor speed signal 112.

Microcontroller 102 includes several peripheral devices that facilitate determining the SoC. A timer 124 generates real-time clock data. A computer memory 126 stores a method and associated data that are described below. A first analog-to-digital converter (A2D) 128 generates battery voltage data that is based on a voltage of battery 104. A second A2D 130 generates battery temperature data based on a battery temperature signal 131. A third A2D 132 generates current data based on a signal 134 indicative of the magnitude and direction, e.g. motoring and regenerating, of the alternating current Iₘₒₜ.

Signal 134 is generated by a current sensor 136 this is connected in series with one of first power lead 114 and second power lead 116. In other embodiments current sensor 136 can be a hall-effect type current sensor that is positioned within a magnetic field generated by the alternating current Iₘₒₜ.

A fourth A2D 138 generates motor voltage data based on a motor voltage across first power lead 114 and second power lead 116. A fifth A2D 140 generates pedal position data based on pedal position signal 118.

A central processing unit (CPU) 160 receives the respective data from clock 124, first A2D 128, second A2D 130, third A2D 132, fourth A2D 138, and fifth A2D 140. CPU 160 also executes the method stored in memory 126 to determine the battery SoC. CPU 160 communicates the SoC to a display 162 that can be monitored by a vehicle user.

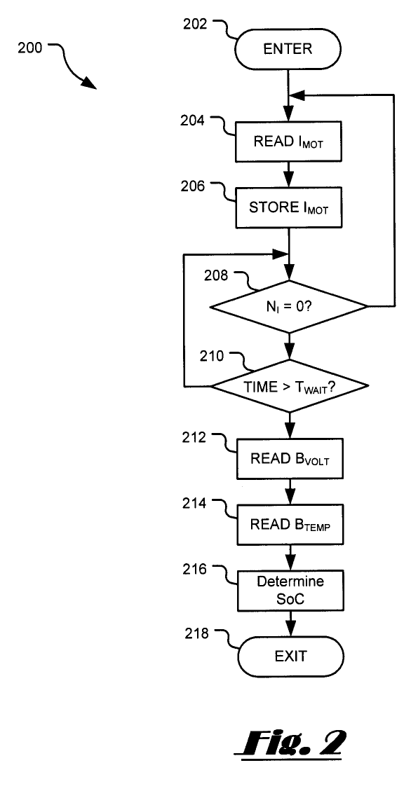

Referring now to FIG. 2, one of several embodiments of a method 200 is shown for determining the SoC of battery 104. Method 200 resides in a portion of memory 126 and is executed by CPU 160.

Control enters at block 202 and immediately proceeds to block 204. In bock 204, control reads motor current data from third A2D 132. The motor current data can be a positive value or negative value depending on whether motor 110 is regenerating or motoring, respectively. Control then proceeds to block 206 and stores into memory 126 the motor current data together with an associated time datum from timer 124. Control then proceeds to decision block 208 and determines whether the motor output speed N_{I} is zero. If not, then control returns to block 204. Alternatively, if the motor output speed N_{I} is zero then control proceeds to decision block 210 and determines whether the motor speed N_{I} has been equal to zero for a predetermined time T_{WAIT}. In some embodiments the predetermined time T_{WAIT} is greater than or equal to two minutes. The predetermined time T_{WAIT} allows the battery voltage to recover after vehicle 100 has been driven. The accuracy of the SoC determination increases as the predetermined time T_{WAIT} increases.

Control returns to decision block 208 if the result from decision block 210 is negative. Control proceeds to block 212 if the result from decision block 210 is affirmative. In block 212, control reads the battery voltage data from first A2D 128. Control then proceeds to block 214 and reads battery temperature data from second A2D 130. Control then proceeds to block 216 and determines the battery SoC based on a summation of the battery current data stored in memory 126, the battery voltage data read in block 212, and the battery temperature data read in block 214. The determination can be made by retrieving the SoC from a lookup table stored in memory 126. The lookup table can be populated with experimentally determined SoC data. Control exits through block 218 after determining the battery SoC.

The description herein is merely exemplary in nature and, thus, variations that do not depart from the gist of that which is described are intended to be within the scope of the teachings. Such variations are not to be regarded as a departure from the spirit and scope of the teachings.

What is claimed is:

1. A system for determining battery state-of-charge (SoC) in an electric vehicle, comprising:
an inverter that converts battery power to an alternating current;
a current sensor that generates a signal indicative of a magnitude and direction of the alternating current;
a first analog-to-digital converter (A2D) that converts the signal to current data; and
a central processing unit (CPU) that periodically stores a present value of the current data to an associated memory and determines the SoC based on the stored current data.

2. The system of claim 1 wherein the CPU stores in a memory corresponding time data with the current data.

3. The system of claim 1 wherein the CPU accesses a look-up table to determine the SoC.

4. The system of claim 1 further comprising:
a temperature sensor that generates battery temperature signal; and
a second A2D that generates battery temperature data based on the battery temperature signal, wherein the CPU determines the SoC based on the stored current data and the temperature data.

5. The system of claim 1 further comprising a clock that generates time data, wherein the CPU determines the SoC after the time data indicates a predetermined period has passed.

6. The system of claim 5 wherein the alternating current is equal to zero during the predetermined time.

7. The system of claim 1 further comprising a third A2D that generates battery voltage data based on a voltage of the battery power, wherein the CPU determines the SoC based on the stored current data and the battery voltage data.

8. A method for determining battery state-of-charge (SoC) in an electric vehicle, comprising:
converting battery power to an alternating current;
generating a signal indicative of a magnitude and direction of the alternating current;
converting the signal to current data;
periodically storing a present value of the current data; and
determining the SoC based on the stored current data.

9. The method of claim 8 wherein the periodically storing step includes storing corresponding time data with the current data.

10. The method of claim 8 further comprising accessing a look-up table to determine the SoC.

11. The method of claim 8 further comprising:
generating battery temperature signal; and
generating battery temperature data based on the battery temperature signal, wherein the SoC is determined based on the stored current data and the temperature data.

12. The method of claim 8 further comprising generating time data, wherein the SoC is determined after the time data indicates a predetermined period has passed.

13. The method of claim 12 wherein the alternating current is equal to zero during the predetermined time.

14. The method of claim 13 further comprising generating battery voltage data based on a voltage of the battery power, wherein the SoC is determined based on the stored current data and the battery voltage data.

15. A system for determining battery state-of-charge (SoC) in an electric vehicle, comprising:
inverter means for converting battery power to an alternating current;
current sensor means for generating a signal indicative of a magnitude and direction of the alternating current;
first converter means for converting the signal to current data; and
processing means for periodically storing a present value of the current data to memory means for storing data and for determining the SoC based on the stored current data.

16. The system of claim 15 wherein the processing means stores in the memory means corresponding time data with the current data.

17. The system of claim 15 wherein the processing means accesses look-up table means for determining the SoC.

18. The system of claim 15 further comprising:
temperature sensing means for generating a battery temperature signal; and
second converter means for generating battery temperature data based on the battery temperature signal, wherein the processing means determines the SoC based on the stored current data and the temperature data.

19. The system of claim 15 further comprising clock means for generating time data, wherein the processing means determines the SoC after the time data indicates a predetermined period has passed.

20. The system of claim 19 wherein the alternating current is equal to zero during the predetermined time.

21. The system of claim 15 further comprising third converter means for generating battery voltage data based on a voltage of the battery power, wherein the processing means determines the SoC based on the stored current data and the battery voltage data.
